(19) United States
(12) Patent Application Publication
(10) Pub. No.: US 2011/0085366 A1
(43) Pub. Date: Apr. 14, 2011

(54) DEVICE

(75) Inventor: Yoshiro Riho, Tokyo (JP)

(73) Assignee: Elpida Memory, Inc., Tokyo (JP)

(21) Appl. No.: 12/889,976

(22) Filed: Sep. 24, 2010

(30) Foreign Application Priority Data
Oct. 14, 2009 (JP) 2009-237229

(51) Int. Cl. G11C 5/02

(52) U.S. Cl. 365/51; 365/63

(57) ABSTRACT

A device includes first to N-th (N is an integer of 2 or more) semiconductor chips stacked. These semiconductor chips have substantially the same configuration, and each includes an identification flag memory circuit including first to N-th memory units and a plurality of through electrodes connected to the identification flag memory circuit. Each of the through electrodes is connected to or masked with respect to the corresponding one of the through electrodes of the underlying semiconductor chip, such that an identification flag is stored in n-th (n indicates 1, 2, . . . , and N) memory units of the n-th semiconductor chips sequentially in the stacking order in response to a clock signal input in common to the first to N-th semiconductor chips, and the storage of the identification flag in the N-th memory unit of the N-th semiconductor chip can be detected from the lower side of the first semiconductor chip.

This application is based upon and claims the benefit of priority from Japanese patent application No. 2009-237229, filed on Oct. 14, 2009, the disclosure of which is incorporated herein in its entirety by reference.

### BACKGROUND OF THE INVENTION

This invention relates to a device, and particularly to a stacked semiconductor device having a plurality of semiconductor chips stacked on one another.

In a semiconductor device having a plurality of semiconductor chips, a specific identification number must be assigned to each of the semiconductor chips in order to identify the semiconductor chips. This applies also to a stacked semiconductor device having a plurality of semiconductor memory chips stacked on one another.

In a stacked semiconductor device according to a related technique, an arithmetic circuit is provided in each of stacked semiconductor chips such that an output of the arithmetic circuit of a lower semiconductor chip is input to the arithmetic circuit of the semiconductor chip stacked thereon, whereby a specific identification number is generated in each of the semiconductor chips. This type of semiconductor device is disclosed, for example, in Japanese Laid-Open Patent Publication No. 2007-157266 (Patent Document 1).

### SUMMARY

Patent Document 1 describes that an operational output of the uppermost arithmetic circuit is used to determine the number of stacked semiconductor chips.

However, the stacked semiconductor device described in Patent Document 1 is not capable of determining whether or not a correct identification number has been assigned to each of the semiconductor chips. Specifically, even if an erroneous identification number is assigned to one or more semiconductor chips due to occurrence of an error or the like in any of the arithmetic circuits, the semiconductor device according to Patent Document 1 is not capable of detecting this erroneous assignment of the identification numbers. The present invention seeks to solve one or more of the above problems, or to improve upon those problems at least in part.

In one embodiment, there is a provided a device that includes first to N-th (N is an integer of 2 or more) semiconductor chips. The first to N-th semiconductor chips have substantially the same configuration. Each of the first to N-th semiconductor chips includes an identification flag memory circuit including first to N-th memory units and a plurality of through electrodes connected to the identification flag memory circuit. Each of the plurality of through electrodes is connected to or masked with respect to the corresponding one of the through electrodes of the underlying semiconductor chip such that an identification flag is sequentially stored in n-th (n is 1, 2, . . . , and N) memory units of n-th semiconductor chips in stacking order in response to a clock signal input in common to the first to N-th semiconductor chips, and that storage of the identification flag in the N-th memory unit of the N-th semiconductor chip can be detected from a lower side of the first semiconductor chip.

In another embodiment, there is a provided a device that includes an identification flag memory circuit including first to N-th memory units. Through electrodes are respectively connected to the input of the first memory unit and first switches which are respectively connected to the outputs of the first to N-th memory units. The inputs of the second to N-th memory units are respectively connected, via second switches, to the through electrodes connected to the outputs of the first to (N−1)th memory units.

In still another embodiment, there is a provided a method of storing an identification flag in a device that includes storing an identification flag sequentially in n-th (n indicates 1, 2, . . . and N) memory units of n-th semiconductor chips in the stacking order in response to a clock signal input in common to first to N-th (N is an integer of 2 or more) stacked semiconductor chips; and externally notifying that the identification flag has been stored in the N-th memory unit of the N-th semiconductor chip.

According to this invention, there is provided a stacked semiconductor device formed by stacking first to N-th semiconductor chips each of which has first to N-th memory units, in which an identification flag is stored in n-th (n indicates 1, 2, and N) memory units of n-th semiconductor chips sequentially in the stacking order. Accordingly, it is possible to determine whether or not the identification flag has been appropriately stored in all the semiconductor chips by detecting that the identification flag has been stored in the N-th memory unit of the N-th semiconductor chip. Moreover, the use of through electrodes eliminates the need of providing any special wiring, making it possible to realize a simple configuration for the semiconductor device.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a diagram showing a schematic configuration of a stacked semiconductor device according to a first embodiment of this invention;

FIG. 2A is a diagram showing a state before formation of a through-silicon via in a SDRAM chip included in the stacked semiconductor device shown in FIG. 1;

FIG. 2B is a diagram showing a connection arrangement of a through-silicon via;

FIG. 2C is a diagram showing a mask arrangement of the through-silicon via;

FIG. 3 is a diagram showing a configuration of an identification flag memory circuit used in the stacked semiconductor device shown in FIG. 1;

FIG. 4 is a circuit diagram showing a configuration of a memory unit included in the identification flag memory circuit shown in FIG. 3;

FIG. 5 is a circuit diagram showing a configuration of an SR flip-flop included in the identification flag memory circuit shown in FIG. 3;

FIG. 6 is a circuit diagram showing a configuration of a switch included in the identification flag memory circuit shown in FIG. 3;

FIG. 7 is a diagram showing signal waveforms observed in various parts of the stacked semiconductor device shown in FIG. 1;

FIG. 8 is a circuit diagram showing particulars of a CS-DQ decoder included in the stacked semiconductor device shown in FIG. 1; and

FIG. 9 is a diagram showing a configuration example of a stacked semiconductor device according to a second embodiment of this invention.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

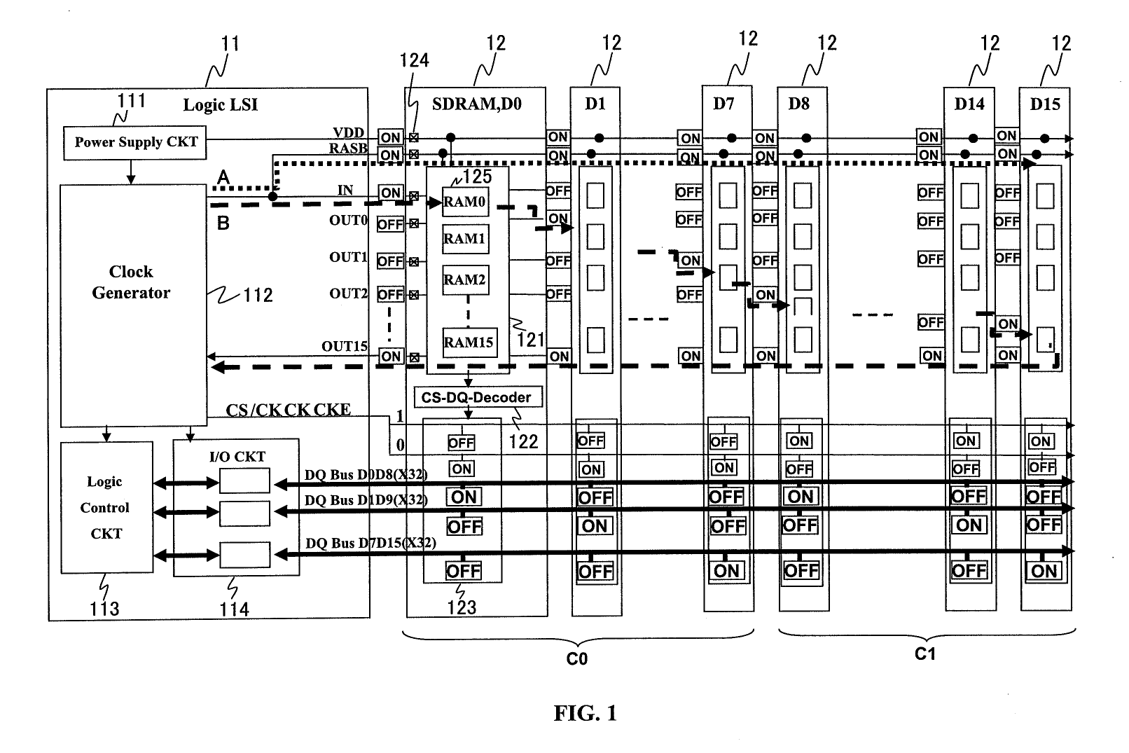

FIG. 1 is a diagram showing a schematic configuration of a stacked semiconductor device according to a first embodiment of this invention. In the description here, the stacked semiconductor device is assumed to be a SDRAM (Synchronous Dynamic Random Access Memory) system. In other words, each semiconductor chip to be stacked is assumed to be a SDRAM chip. It should be noted that, in the following description, a semiconductor chip is sometimes referred to as a semiconductor device.

The stacked semiconductor device shown in FIG. 1 includes a logic LSI (Large Scale Integration) 11, and first to N-th (N is an integer of 2 or more, and here N is 16) SDRAM chips (D0 to D15) 12.

The logic LSI 11 includes a power supply circuit 111, a clock generator 112, a logic control circuit 113, and an input/output circuit 114. The first to N-th SDRAM chips 12, having substantially the same configuration, are stacked one on another. These stacked SDRAM chips 12 are modularized to form a DIMM (Dual Inline Memory Module). The DIMM is provided with common pins for all the chips (for address signals and command signals), chip selection control pins (for chip selection signals and clock signals), and data (DQ) pins so that the DIMM is connected to the logic LSI 11 using these pins. Each of the SDRAM chips 12 has through electrodes corresponding to these pins. However, in FIG. 1, only some of these through electrodes (indicated by the reference numeral 124) are shown.

Each of the SDRAM chips 12 includes an identification flag memory circuit 121, a CS-DQ (Chip Select-Data) decoder circuit 122, a pin control circuit 123, and a plurality of through electrodes (TSVs, or Through Silicon Vias) 124. The identification flag memory circuit 121 has N memory units (RAM0 to RAM15) 125. Herein, illustration and description will be omitted of common components, which are not directly related to the invention, such as a DRAM array, X and Y decoders or the like.

The power supply circuit 111 in the logic LSI 11 generates a power supply voltage (VDD). The clock generator 112 generates one of signals that can be supplied to all the SDRAM chips 12, for example, an inverted low address strobe signal (RASB). An RASB is a continuous periodic pulse signal which is used not only as an operational clock signal for the identification flag memory circuit 121, but also for generation of an identification flag. The clock generator 112 also generates a chip selection signal (CS), a clock signal (CK), an inverted clock signal (CKB), and a clock enable signal (CKE).

The signals from the logic LSI 11 are supplied to the DIMM through the various pins described above. At least some of the pins are connected to the through electrodes 124 formed in the first SDRAM chip (D0) 12.

The through electrodes 124 of each of the second to N-th SDRAM chips 12 are connected to or masked with respect to the corresponding through electrodes of the SDRAM chip 12 located beneath the same in a manufacturing or stacking process. The through electrodes of the first SDRAM chip 12 are connected to or masked with respect to corresponding electrodes formed in a base such as an interposer (not shown). This means that the first SDRAM chip 12 is connected to the logic LSI 11 through an interposer or the like.

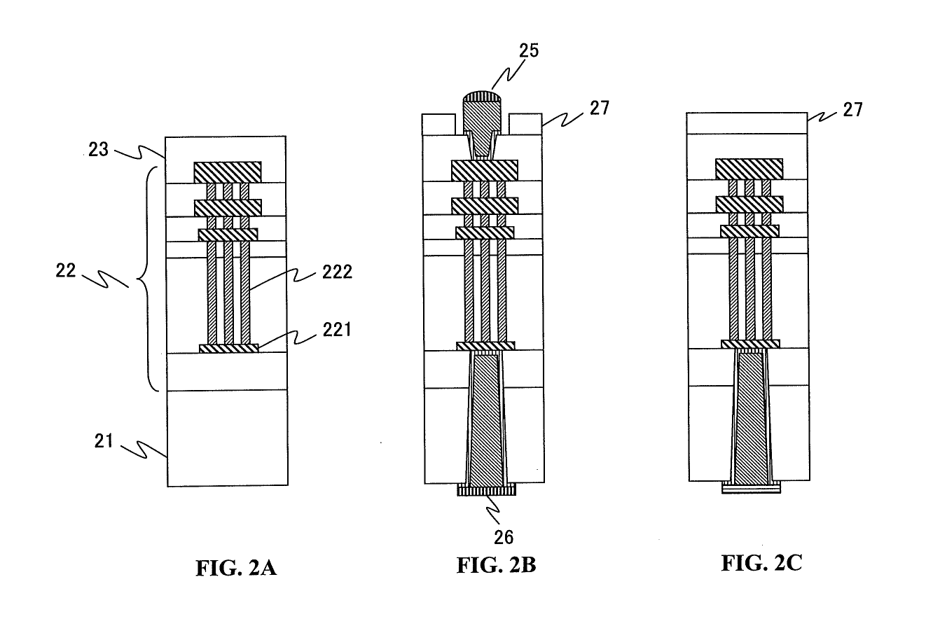

The through electrode 124 will be described with reference to FIGS. 2A to 2C. As shown in FIG. 2A, the SDRAM chip 12 has a silicon substrate 21, a device wiring layer 22 formed on the silicon substrate 21, and a protection layer 23. There are formed, in the device wiring layer 22, a wiring layer 221 and vias 222 forming a part of the through electrode 124.

The SDRAM chips 12 can be manufactured by a known method. FIG. 2A shows a state of a SDRAM chip 12 which has gone through a wafer processing. The SDRAM chip 12 is in a wafer state. A wafer test (electrical test) is performed using a tester (not shown) before formation of the protection layer 23, that is, in the state in which the uppermost wiring layer is exposed.

When the SDRAM chips 12 are stacked, an intermediate process is performed before performing an assembly/packaging, in order to enable electrical connection between upper and lower SDRAM chips. Specifically, as shown FIG. 2B, connection bumps (a top bump 25 and a bottom bump 26) are formed on the top and back faces, respectively. No top bump 25 is formed for the through electrode 124 which is masked with respect to the SDRAM chip or the like located beneath the same. Consequently, as shown in FIG. 2C, the masked through electrode 124 assumes a state in which the uppermost wiring layer is covered with the protection layers 23 and 27 which are insulation films. As is obvious from this description, in the description of this embodiment of the invention, the expression that a plurality of SDRAM chips have substantially the same configuration refers to that the SDRAM chips have the same configuration except the arrangement of the top bumps 25.

Referring again to FIG. 1, it is indicated by “ON” or “OFF” whether or not the through electrodes 124 of each chip are connected to corresponding (through) electrodes in the underlying chip. More specifically, “ON” is indicated on the left side of each chip if a through electrode 124 is connected to the underlying one, whereas “OFF” is indicated if a through electrode 124 is masked. It should be noted that FIG. 1 shows only those through electrodes 124 directly related to this invention, that is, those through electrodes 124 connected to the identification flag memory circuit 121, whereas the through electrodes not directly related to the invention are omitted from the illustration.

Describing more particularly, in each of the SDRAM chips 12, the VDD and RASB through electrodes 124 are connected to their corresponding electrodes in the underlying chip. The through electrode (OUT15) 124 connected to the output of the N-th (N=16) memory unit (RAM15) 125 is also connected to its corresponding electrode in the underlying chip.

On the other hand, the through electrodes (IN and OUT0 to OUT14) 124 connected to the inputs of the first to sixteenth memory units (RAM0 to RAM15) 125 are connected to their corresponding through electrodes 124 in the underlying chip according to the position where the SDRAM chip 12 is stacked. Specifically, in the case of the n-th (n indicates 1, 2, . . . , and N) SDRAM chips (Dn−1) 12, the through electrodes 124 connected to the inputs of the n-th memory units (RAMn−1) 125 are connected to their corresponding through electrodes 124 in the underlying chips, while the through electrodes 124 connected to the inputs of the other memory units 125 are masked with respect to their corresponding through electrodes 124 in the underlying chips.

The through electrodes 124 connected to the inputs of the n-th memory units (RAMn−1) 125 are connected also to the outputs of the (n−1)th memory units (RAMn−2) 125 except when n is 1. Therefore, as described above, the through electrodes 124 connected to the inputs of the n-th memory units (RAMn−1) 125 are connected to their corresponding electrodes in the underlying chip, whereby the identification flag can be stored sequentially in the n-th memory units (RAMn−1) of the n-th SDRAM chips (Dn−1), namely, first in the first memory unit (RAM0) of the first SDRAM chip (D0), then in the second memory unit (RAM1) of the second SDRAM chip (D1), then in the third memory unit (RAM2) of the third SDRAM chip (D2), and so on up to the N-th memory unit (RAM15) of the N-th (N=16) SDRAM chip (D15). It can be notified that the identification flag has been stored in the N-th memory unit (RAM15) of the N-th (N=16) SDRAM chip (D15) from the N-th (N=16) SDRAM chip (D15) to all other SDRAM chips 12 and the logic LSI 11.

Next, operation of the stacked semiconductor device of FIG. 1 will be described.

Upon receiving power supply from the power supply circuit 111, the stacked semiconductor device enters a self-identification mode, and the clock generator 112 generates a RASB signal, that is a continuous periodic pulse signal. The RASB signal is split into two in the logic LSI 11, one being output as a clock signal, and the other being output as an identification flag. Specifically, one of the split RASB signals is supplied to all the SDRAM chips 12 through the RASB through electrodes 124 (indicated by the broken-line arrow A), while the other is supplied to the through electrode 124 connected to the input of the first memory unit (RAM0) of the first SDRAM chip (D0) 12.

Upon receiving the supply of a power supply voltage VDD from the power supply circuit 111 and the RASB signal from the clock generator 112, the identification flag memory circuit 121 of each of the SDRAM chips 12 operates using the RASB signal as an operation clock signal.

First, upon receiving the first clock pulse, an identification flag is held in the first memory unit (RAM0) 125 of the first SDRAM chip (D0) 12. Upon receiving the second clock pulse, the identification flag held in the first memory unit (RAM0) 125 of the first SDRAM chip (D0) 12 is loaded into and held in the second memory unit (RAM1) 125 of the second SDRAM chip (D1) 12. After this, the identification flag is loaded sequentially into the n-th memory units (RAMn−1) 125 of the n-th SDRAM chips (Dn−1) 12 (indicated by the broken-line arrow B) in response to clock pulses. In this manner, the identification flag is stored in the identification flag memory circuits 121 of all the SDRAM chips 12. The position (memory unit) where the identification flag is stored differs among all the SDRAM chips 12. Therefore, the storage of the identification flag as described above gives the same effects as that obtained by assigning different identification numbers to all the SDRAM chips 12.

Finally, once the identification flag has been held in the N-th memory unit (RAM15) 125 of the N-th SDRAM chip (D15) 12, this fact is notified to all the SDRAM chips 12 and the logic LSI 11. This notification stops the supply of the RASB signal to the identification flag memory circuits 121, whereby their memory contents are fixed. The logic LSI 11 is allowed by this notification to determine that identification numbers have been assigned appropriately to all the SDRAM chips 12.

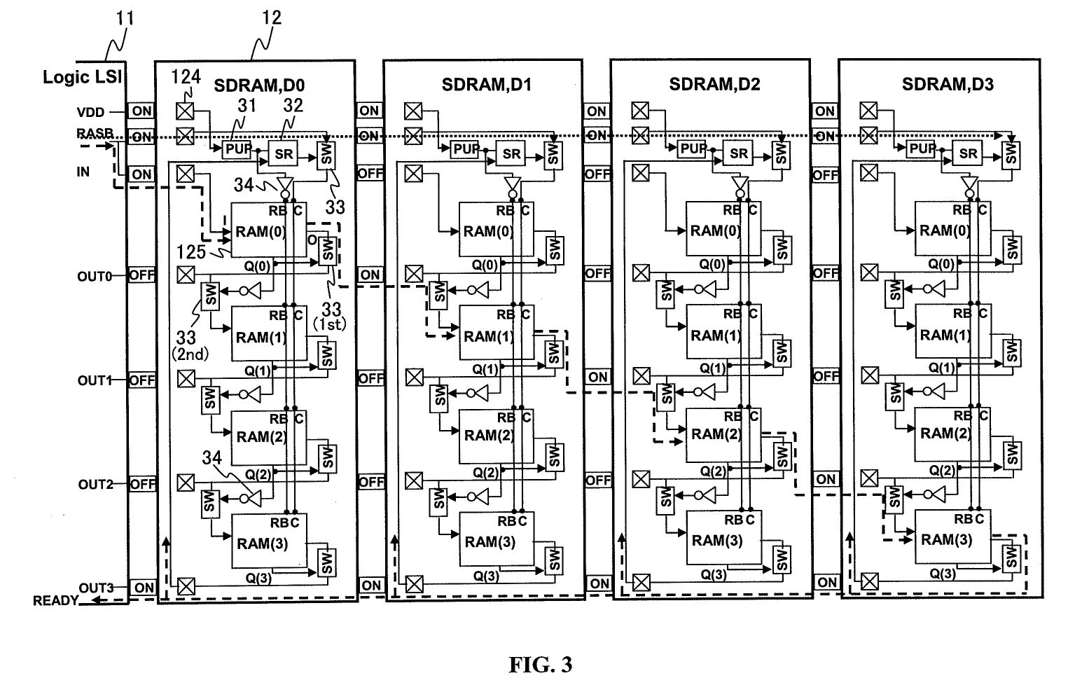

Referring to FIGS. 3 to 8, the stacked semiconductor device according to this first embodiment will be described in further detail.

FIG. 3 is a diagram showing an internal configuration of the identification flag memory circuit 121. Unlike FIG. 1, FIG. 3 illustrates a case in which N is 4 in order to simplify the description thereof.

As shown in FIG. 3, the identification flag memory circuit 121 includes N memory units 125, and each SDRAM chip 12 has a one-shot pulse generator (PUP) 31, an SR flip-flop (SR) 32, a plurality of switches (SW) 33, and a plurality of inverters 34. The switches 33 connected directly to the outputs of the memory units 125 are sometimes referred to as first switches, and the switches 33 connected directly to the inputs of the memory units 125 are sometimes referred to as second switches.

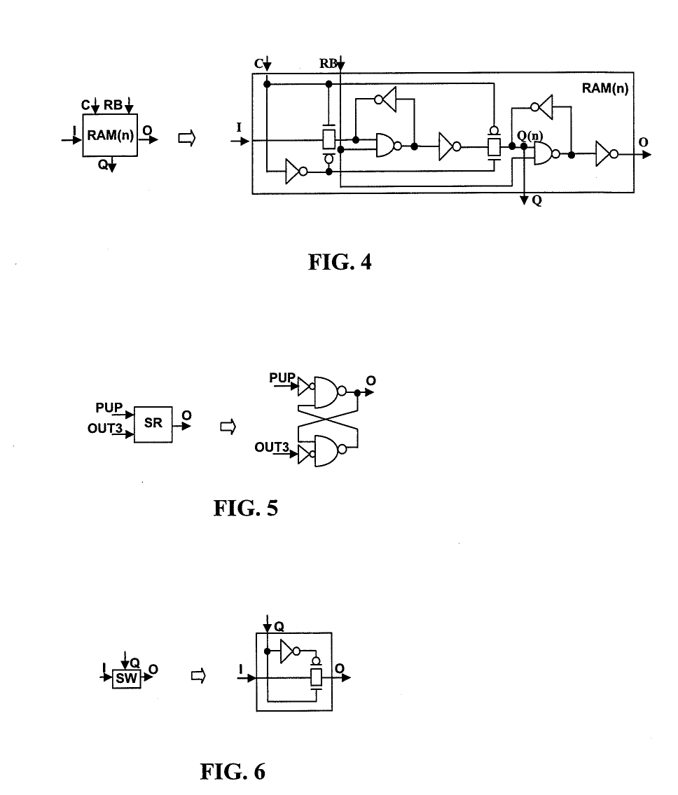

Each of the memory units 125 is formed, for example, of a MOS transistor, a NAND circuit, and an inverter, as shown in FIG. 4. The SR flip-flop 32 is formed, for example, of a NAND circuit and an inverter, as shown in FIG. 5. Each of the switches 33 is formed, for example, of a MOS transistor and an inverter, as shown in FIG. 6.

In the configuration as described above, the self-identification mode is entered upon power being turned on, and the one-shot pulse generator 31 of each of the SDRAM chips 12 outputs a one-shot pulse. This pulse is split into two, one of which is supplied to an inverted reset terminal (RB) of each of the memory units 125 through the inverter 34 to reset the memory content in the memory unit 125. The other split pulse is supplied to one of the inputs of the SR flip-flop 32 to render its output level high. This turns on the switch 33 connected to the output of the SR flip-flop 32, and the RASB signal supplied from the logic LSI 11 to all the SDRAM chips 12 is supplied, as a clock signal, to a clock terminal (C) of each of the memory units 125.

Subsequently, according to the RASB (clock) signal input to the clock terminal, each of the memory units 125 holds the signal level of an input signal (I) as an identification flag and outputs the signal level thus held as a switch control signal (Q) and an output signal (O).

More specifically, the first memory unit (RAM0) 125 of the first SDRAM chip (D0) 12, which is supplied with a RASB signal from the logic LSI 11 as an input signal (I), is activated by a clock input, holds the high level of the input signal, namely the RASB signal (identification flag) on the leading edge of the clock signal, and outputs the high level thus held as a switch control signal (Q) and an output signal (O) on the trailing edge of the clock signal.

The switch control signal (Q) from the first memory unit (RAM0) 125 of the first SDRAM chip (D0) 12 controls two switches 33 to supply the output signal (O) from the first memory unit (RAM0) 125 to the through electrode 124 and to inhibit the supply of the output signal (O) to the input terminal of the second memory unit (RAM1) 125.

The through electrode 124 connected to the output of the first memory unit (RAM0) 125 of the first SDRAM chip (D0) 12 is connected to another through electrode 124 formed at the same position in the second SDRAM chip (D1) 12. Since no signal is input to the first memory unit (RAM0) 125 of the second SDRAM chip (D1) 12 (the through electrode 124 connected to the input thereof is masked), the switches 33 controlled by the switch control signal, or an output of the first memory unit (RAM0) 125 of the second SDRAM chip (D1) 12 supplies the output signal from the first memory unit (RAM0) 125 of the first SDRAM chip (D0) 12 to the second memory unit (RAM1) 125 of the second SDRAM chip (D1) 12.

The second memory unit (RAM1) 125 of the second SDRAM chip (D1) 12 holds the input signal in response to the next leading edge of the clock signal, and outputs the held signal level as a switch control signal (Q) and an output signal (O) in response to the subsequent trailing edge of the clock signal.

The identification flag is likewise stored sequentially in the third memory unit (RAM2) 125 of the third SDRAM chip (D2) 12, in the fourth memory unit (RAM3) 125 of the fourth SDRAM chip (D3) 12, and onwards.

An output signal is output also when the identification flag is stored in the fourth memory unit (RAM3) 125 of the fourth SDRAM chip (D3) 12, in the same manner as when the identification flag is stored in the other memory units. This output signal is supplied not only to the logic LSI 11 as a READY signal but also to the other input of the SR flip-flop 32 of each of the SDRAM chips 12. Upon receiving the READY signal, the SR flip-flop 32 changes its output to a low level, whereby the switch 33 connected to the SR flip-flop 32 is turned off to inhibit the supply of a clock signal to the memory units 125. This means that the SR flip-flop 32 and the switch 33 connected thereto operate as a clock signal inhibiting circuit. The supply of a clock signal to the memory units 125 is thus stopped, whereby the memory content of the identification flag memory circuit 121 in each of the SDRAM chips 12 is fixed. Since the identification flag is stored in respectively different memory units (at the different positions) of the SDRAM chips 12, the same effect can be obtained as when specific identification numbers are assigned respectively to the SDRAM chips 12.

Upon receiving the READY signal, the logic LSI 11 determines that the identification flag has been stored appropriately in all the SDRAM chips 12 and exits from the self-identification mode.

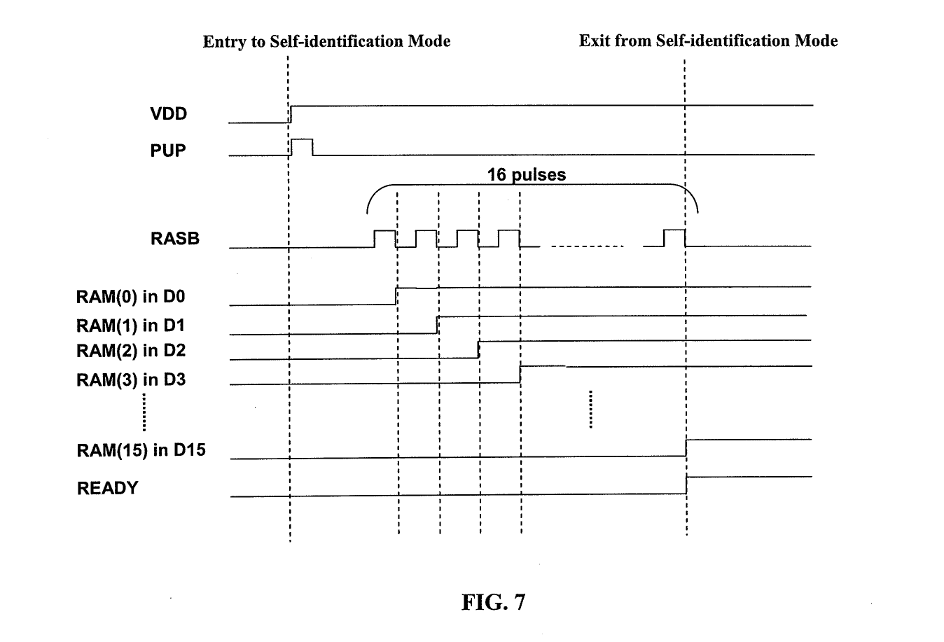

FIG. 7 is a diagram showing signal waveforms observed at various parts of the stacked semiconductor device when N is 16. It can be seen from FIG. 7 that an identification flag is stored sequentially in the n-th memory units 125 of the n-th SDRAM chips 12.

The identification flag (here, the switch control signal Q instead of the output signal O) stored in the identification flag memory circuit 121 is then supplied to the CS-DQ decoder circuit 122 (see FIG. 1). In each of the n-th SDRAM chips 12, an identification flag in which the signal Q(n−1) is high level while the other signals Q are low level is supplied to the CS-DQ decoder circuit 122.

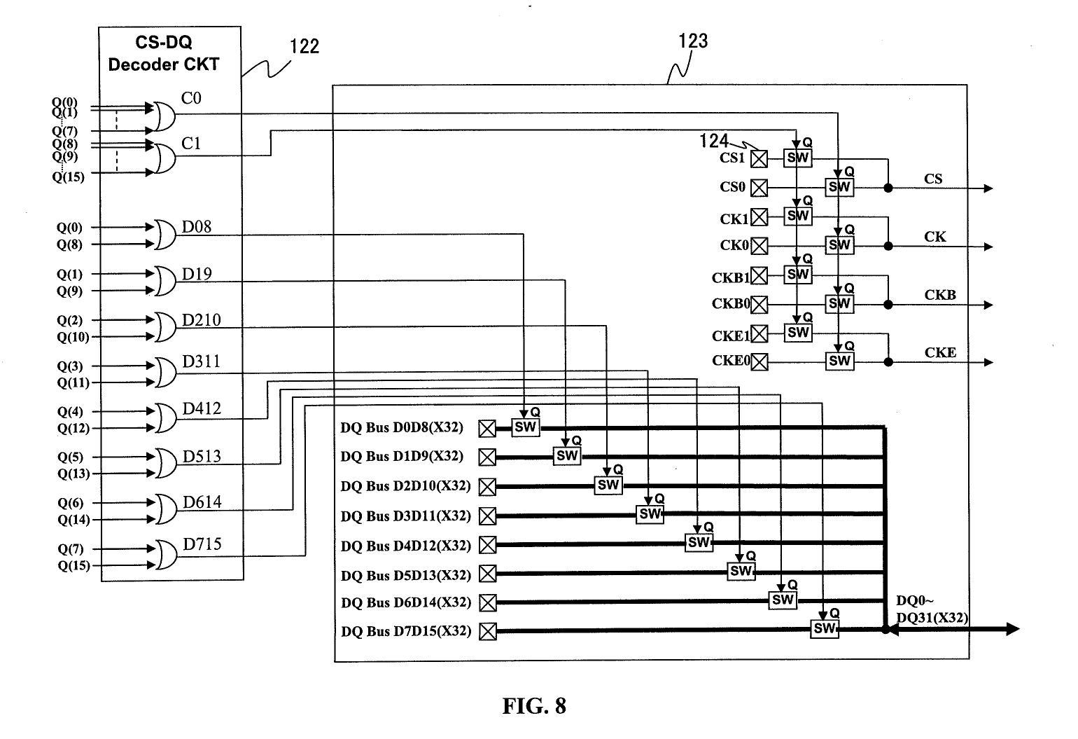

The CS-DQ decoder circuit 122 is formed, for example, by a plurality of OR circuits as shown in FIG. 8, and its output is used to control chip selection control pins and data pins (pin control circuit 123). Switches (SW) included in the pin control circuit 123 are formed in the same manner as the switches included in the identification flag memory circuit 121 (for example, as shown in FIG. 6).

As seen from FIG. 8, when any one of the signals Q(0) to Q(7) of the first to eighth SDRAM chips 12 is at a high level and the other signals Q are at a low level, CS0, CK0, CKB0 and CKE0 are selected as CS, CK, CKB and CKE, respectively. When any one of the signals Q(8) to Q(15) of the ninth to 16th SDRAM chips 12 is at a high level and the other signals Q are at a low level, CS1, CK1, CKB1 and CKE1 are selected as CS, CK, CKB and CKE, respectively.

For the same reason, in each of the SDRAM chips 12, one of eight DQ buses is selected for 32-bit data signals DQ0 to DQ31.

In the stacked semiconductor device according to this first embodiment as described above, different identification numbers can be assigned to the respective stacked semiconductor chips, and this can be detected from the lower side of the first semiconductor chip (i.e. by the logic LSI 11). Moreover, the stacked semiconductor device according to this embodiment eliminates the need of an increment circuit or the like for performing computation, and hence the configuration can be simplified.

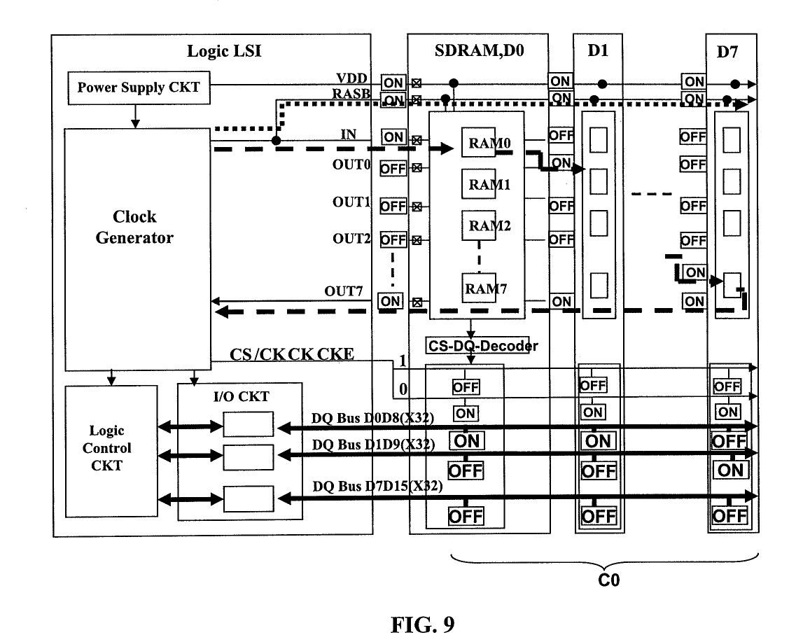

Referring to FIG. 9, a semiconductor device according to a second embodiment of this invention will be described.

The semiconductor device shown in FIG. 9 is formed by stacking eight SDRAM chips (D1 to D7). The number of stacked SDRAM chips is a half of the number of the stacked SDRAM chips in the semiconductor device according to the first embodiment. Therefore, the number of RAMs (0 to 7) provided in each of the SDRAM chips is also a half of that in the semiconductor device according to the first embodiment. Operation of the semiconductor device according to the second embodiment is the same as that of the semiconductor device according to the first embodiment, and thus further description thereof will be omitted.

The semiconductor device shown in FIG. 9 may be formed by using different SDRAM chips from those used in the semiconductor device of the first embodiment, that is to say, by using dedicated SDRAM chips for the semiconductor device of the second embodiment. However, according to this invention, the semiconductor device of FIG. 9 can be formed by using the same SDRAM chips 12 as those used in the semiconductor device of the first embodiment.

Specifically, the semiconductor device of FIG. 9 can be formed with the use of the SDRAM chips 12 for use in the semiconductor device of the first embodiment by forming top bumps (see FIGS. 2B and 2C) only at necessary spots during an intermediate process performed between a wafer processing and an assembly/packaging. In other words, the SDRAM chips 12 used in the first embodiment can be made selectively usable between in a first specification for the semiconductor device of FIG. 1 and in a second specification for the semiconductor device of FIG. 9, by making it possible to selectively form, in the intermediate process, a connection bump (25 in FIG. 2B) (or an insulation film (23 and 27 in FIG. 2C) at one end of each of the through electrodes. This also means that the SDRAM chips 12 can be shipped out as versatile products in the state in which they have undergone the wafer processing (in the state of wafer).

Although this invention has been described above in terms of several preferred embodiments thereof, it will be appreciated by those skilled in the art that those embodiments are provided solely for illustrating the invention, and should not be relied upon to construe the appended claims in a limiting sense. That is, the invention is not limited to these embodiments but various changes and modification can be made without departing from the scope of the invention. For example, the semiconductor chips to be stacked are not limited to SDRAM chips but may be another type of semiconductor chips. The number N of the stacked semiconductor chips can be chosen arbitrarily.

What is claimed is:

1. A device comprising first to N-th (N is an integer of 2 or more) semiconductor chips, wherein:
the first to N-th semiconductor chips have substantially the same configuration;
each of the first to N-th semiconductor chips includes an identification flag memory circuit including first to N-th memory units and a plurality of through electrodes connected to the identification flag memory circuit; and
each of the plurality of through electrodes is connected to or masked with respect to the corresponding one of the through electrodes of the underlying semiconductor chip such that an identification flag is sequentially stored in n-th (n is 1, 2, . . . , and N) memory units of n-th semiconductor chips in stacking order in response to a clock signal input in common to the first to N-th semiconductor chips, and that storage of the identification flag in the N-th memory unit of the N-th semiconductor chip can be detected from a lower side of the first semiconductor chip.

2. The device according to claim 1, further comprising a logic LSI provided beneath the first to N-th semiconductor chips to supply the clock signal and the identification flag to the first semiconductor chip.

3. The device according to claim 1, wherein:
in each of the first to N-th semiconductor chips, outputs of the first to (N−1)th memory units are respectively connected, via first switches, to the through electrodes which are respectively connected to inputs of the second to Nth memory units via second switches; and
in an n-th semiconductor chip, the through electrode connected to the input of the n-th memory unit is connected to the corresponding one of the through electrodes of the underlying semiconductor chip, while the through electrodes connected to the inputs of the other memory units than the n-th memory unit are masked with respect to the corresponding ones of the through electrodes of the underlying semiconductor chip, and the through electrode connected to the output of the N-th memory unit is connected to the corresponding one of the through electrodes of the underlying semiconductor chip.

4. The device according to claim 3, wherein, in the n-th semiconductor chip, the n-th memory unit turns on the first switch connected to the output of the n-th memory unit upon input of the identification flag, and if there is provided an (n+1)th memory unit, the n-th memory unit turns off the second switch connected to the input of the (n+1)th memory unit.

5. The device according to claim 1, wherein each of the first to N-th semiconductor chips comprises a clock inhibiting circuit which is connected to the through electrode connected to the output of the N-th memory unit via a switch, and inhibits the supply of a clock signal to the identification flag memory circuit when detecting that the identification flag has been stored in the N-th memory unit of the N-th semiconductor chip.

6. A device comprising:
an identification flag memory circuit including first to N-th memory units; and
through electrodes respectively connected to the input of the first memory unit and first switches which are respectively connected to the outputs of the first to N-th memory units,
wherein the inputs of the second to N-th memory units are respectively connected, via second switches, to the through electrodes connected to the outputs of the first to (N−1)th memory units.

7. The device according to claim 6, wherein n-th (n is 1, 2, . . . , or N) memory unit turns on the first switch connected to the output of the n-th memory unit upon input of the identification flag, and if there is provided an (n+1)th memory unit, the n-th memory unit turns off the second switch connected to the input of the (n+1)th memory unit.

8. The device according to claim 6, wherein a connection bump is selectively formed at one ends of the through electrodes.

9. A method of storing an identification flag in a device comprising:
storing an identification flag sequentially in n-th (n indicates 1, 2, . . . and N) memory units of n-th semiconductor chips in the stacking order in response to a clock signal input in common to first to N-th (N is an integer of 2 or more) stacked semiconductor chips; and
externally notifying that the identification flag has been stored in the N-th memory unit of the N-th semiconductor chip.
